(19) United States
(12) Patent Application Publication
(10) Pub. No.: US 2020/0220532 A1
(43) Pub. Date: Jul. 9, 2020

(54) CIRCUIT FOR PREVENTING LATCH-UP AND INTEGRATED CIRCUIT

(71) Applicant: Chipone Technology (Beijing) Co., Ltd., Beijing (CN)

(72) Inventors: Tianhao Chen, Beijing (CN); Junjie WU, Beijing (CN)

(73) Assignee: Chipone Technology (Beijing) Co., Ltd., Beijing (CN)

(21) Appl. No.: 16/628,017

(22) PCT Filed: Mar. 19, 2019
(86) PCT No.: PCT/CN2019/078701

§ 371 Date: Dec. 31, 2019

(30) Foreign Application Priority Data
Mar. 20, 2018 (CN) 201810227939.X

(51) Int. Cl. H03K 17/081; H03K 17/082; H03K 17/60; H03K 17/687

(52) U.S. Cl. CPC H03K 17/081; H03K 17/6872; H03K 17/60; H03K 17/0826

(57) ABSTRACT

Disclosed is an circuit for preventing latch-up, comprising a first transistor, a second transistor of a type opposite to that of the first transistor, and a control circuit, wherein a control terminal of the first transistor receives a first control voltage and a first terminal of the first transistor receives a first supply voltage; a control terminal of the second transistor receives a second control voltage, and is connected to a second terminal of the first transistor; a first terminal of the second transistor is connected to the control terminal of the first transistor, and a second terminal of the second transistor receives a second supply voltage. The control circuit is coupled on a path formed by the first transistor and the second transistor between the first supply voltage and the second supply voltage for disconnecting the path when the first control voltage and/or the second control voltage is out of a predetermined range.

### CROSS-REFERENCE TO RELATED APPLICATIONS

This application claims priority from Chinese Patent Application No. 201810227939.X, submitted to Patent Office of the People's Republic of China, filed on Mar. 20, 2018 and entitled by “Circuit for preventing latch-up and Integrated circuit”, the entire contents of which are incorporated by reference in the present application.

### FIELD OF TECHNOLOGY

The present invention relates to the technical field of integrated circuit, in particular, to a circuit for preventing latch-up and an integrated circuit.

### BACKGROUND

With the development of IC manufacturing processes, the size of chips is getting smaller and smaller, the density and integration degree of chip packaging are getting higher and higher, accordingly, the possibility of latch-up is increasing, and the possibility of mutual interference between modules will also increase. Parasitic transistors (also known as parasitic thyristors, or SCR for short) exist in general integrated circuits. Latch-up effect means that a parasitic bipolar transistor is triggered to turn on, forming a low-impedance and large-current path between the power supply VDD and the ground GND, resulting in the integrated circuit not working properly or even burning. Such parasitic bipolar transistors have various parts of the integrated circuit, including input terminals, output terminals, internal inverters, and the like.

FIGS. 1 and 2 respectively illustrate a structural view and an equivalent circuit diagram of a parasitic thyristor in the prior art. As shown in FIGS. 1 and 2, the parasitic bipolar transistor consists of a PNP transistor and a lateral NPN transistor. Q1 is a vertical Bipolar Junction Transistor (BJT), wherein a control terminal of Q1 is an N-type well region, a second terminal of Q1 is a P-type substrate, and a first terminal of Q1 is a P-channel. Q2 is a side Bipolar Junction Transistor (BJT), wherein a control terminal of Q2 is a P-type substrate, a second terminal of Q2 is an N-type well region, and a first terminal of Q2 is an N-channel. The above two elements constitute a SCR thyristor circuit. When no external interference has caused a trigger, the two BJTs are in the off state, and the current of the second terminal of Q1 is composed of the reverse leakage current of the second terminal of Q1—the control terminal of Q2, and the current of the second terminal of Q2 is composed of the reverse leakage current of the second terminal of Q2—the control terminal of Q1, so that the current gain of the SCR thyristor circuit is very small and there is no latch-up effect. When the current of the second terminal of one of the BJTs is suddenly increased to a certain value by external interference, it will be fed back to another BJT, so that the two BJTs are turned on by the trigger, and a low-impedance and large-current path is formed between the power supply VDD and the ground GND to generate the latch-up effect. For example, when the voltage VP at the second terminal of Q1 rises and the voltage V_{N} at the second terminal of Q2 falls, a latch-up effect occurs in the SCR thyristor circuit.

### SUMMARY

In view of the above problems, the purpose of the present invention is to provide a circuit for preventing latch-up and an integrated circuit, which is resistant to latch-up.

According to one aspect of the present invention, a circuit for preventing latch-up is provided, comprising a first transistor having a control terminal, a first terminal and a second terminal, a second transistor of a type opposite to that of the first transistor having a control terminal, a first terminal and a second terminal, and a control circuit. The control terminal of the first transistor receives a first control voltage and the first terminal of the first transistor receives a first supply voltage. The control terminal of the second transistor receives a second control voltage, and is connected to the second terminal of the first transistor; the first terminal of the second transistor is connected to the control terminal of the first transistor, and the second terminal of the second transistor receives a second supply voltage. The control circuit is disposed on a path formed by the first transistor and the second transistor between the first supply voltage and the second supply voltage, and is used for disconnecting the path when the first control voltage and/or the second control voltage is out of a predetermined range.

Preferably, the control circuit is coupled between the first supply voltage and the first transistor, and comprises a first comparison module and a first switch module; the first comparison module is used to output a first switch signal for turning off the first switch module when the first control voltage is out of a first predetermined range; the first switch module is used to disconnect the first supply voltage from the first transistor when receiving the first switch signal.

Preferably, the first comparison module is a first comparator, and the first switch module is a first switch transistor; a first input terminal of the first comparator receives the first control voltage, a second input terminal of the first comparator receives a first reference voltage, and the output terminal of the first comparator is connected to a control terminal of the first switch transistor; a first terminal of the first switch transistor receives the first supply voltage, and a second terminal of the first switch transistor is connected to the first terminal of the first transistor.

Preferably, the control circuit is coupled between the second supply voltage and the second transistor, and comprises a second comparison module and a second switch module; the second comparison module is used to output a second switch signal for turning off the second switch module when the second control voltage is out of a second predetermined range; the second switch module is used to disconnect the second supply voltage from the second transistor when receiving the second switch signal.

Preferably, the second comparison module is a second comparator, and the second switch module is a second switch transistor; a first input terminal of the second comparator receives the second control voltage, a second input terminal of the second comparator receives a second reference voltage, and the output terminal of the second comparator is connected to a control terminal of the second switch transistor; a first terminal of the second switch transistor receives the second supply voltage, and a second terminal of the second switch transistor is connected to the first terminal of the second transistor.

Preferably, the control circuit is coupled between the first supply voltage and the first transistor, and between the second supply voltage and the second transistor, and comprises a first comparison module, a first switch module, a second comparison module and a second switch module; the first comparison module is used to output a first switch signal for turning off the first switch module when the first control voltage is out of a first predetermined range; the first switch module is used to disconnect the first supply voltage from the first transistor when receiving the first switch signal; the second comparison module is used to output a second switch signal for turning off the second switch module when the second control voltage is out of a second predetermined range; the second switch module is used to disconnect the second supply voltage from the second transistor when receiving the second switch signal.

Preferably, the first comparison module is a first comparator, and the first switch module is a first switch transistor; the second comparison module is a second comparator, and the second switch module is a second switch transistor; a first input terminal of the first comparator receives the first control voltage, a second input terminal of the first comparator receives a first reference voltage, and the output terminal of the first comparator is connected to a control terminal of the first switch transistor; a first terminal of the first switch transistor receives the first supply voltage, and a second terminal of the first switch transistor is connected to the first terminal of the first transistor; a first input terminal of the second comparator receives the second control voltage, a second input terminal of the second comparator receives a second reference voltage, and the output terminal of the second comparator is connected to a control terminal of the second switch transistor; a first terminal of the second switch transistor receives the second supply voltage, and a second terminal of the second switch transistor is connected to the first terminal of the second transistor.

Preferably, the first switch transistor is a PMOS transistor, and the second switch transistor is an NMOS transistor.

Preferably, the first transistor is a PNP transistor, and the second transistor is an NPN transistor.

Preferably, the first supply voltage is larger than the second supply voltage.

According to another aspect of the present invention, an integrated circuit is provided, comprising the circuit for preventing latch-up described above.

The circuit for preventing latch-up and the integrated circuit provided by the present invention, by introducing the control circuit on the path formed by the first transistor and the second transistor between the first supply voltage and the second supply voltage, can disconnect the path when the first control voltage of the first transistor and/or the second control voltage of the second transistor is out of the predetermined range, so that a latch-up effect is prevented from occurring during power-on phase.

### BRIEF DESCRIPTION OF THE DRAWINGS

The above and other objects, features and advantages of the present invention will become more apparent from the description below with reference to the accompanying drawings. In figures:

FIG. 1 illustrates a structural view of a parasitic thyristor in the prior art;

FIG. 2 illustrates an equivalent circuit diagram of the parasitic thyristor in FIG. 1;

FIG. 3 illustrates a circuit diagram of a circuit for preventing latch-up according to a first embodiment of the present invention;

FIG. 4 illustrates a circuit diagram of a circuit for preventing latch-up according to a second embodiment of the present invention;

FIG. 5 illustrates a circuit diagram of a circuit for preventing latch-up according to a third embodiment of the present invention.

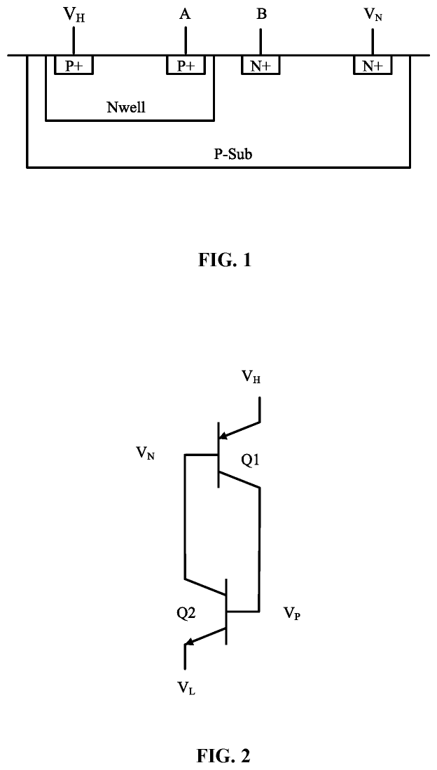

### DESCRIPTION OF THE EMBODIMENTS

Various embodiments of the present invention will be described in more detail below with reference to the accompanying drawings. In the various figures, the same elements are denoted by the same or similar reference numerals. For the sake of clarity, the various parts in the figures are not drawn to scale.

The specific implementation of the invention will be further described in detail in combination with drawings and the embodiment.

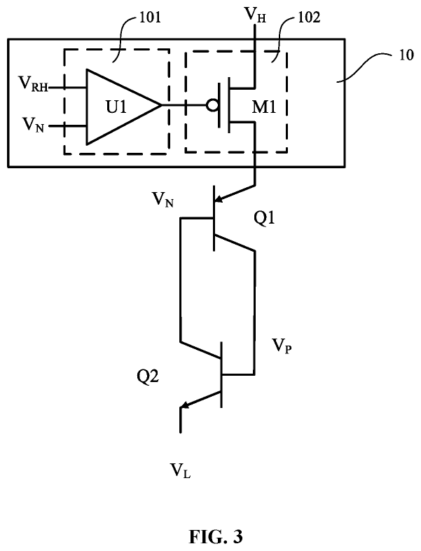

FIG. 3 illustrates a circuit diagram of a circuit for preventing latch-up according to a first embodiment of the present invention. As shown in FIG. 3, the circuit for preventing latch-up comprises a first transistor Q1, a second transistor Q2, and a control circuit 10.

The first transistor Q1 has a control terminal, a first terminal, and a second terminal, wherein the control terminal of the first transistor Q1 is configured to receive a first control voltage V_{N}, and the first terminal of the first transistor Q1 is configured to receive a first supply voltage V_{H}.

The second transistor Q2 is of a type opposite to that of the first transistor Q1, and has a control terminal, a first terminal, and a second terminal the control terminal of the second transistor Q2 is configured to receive a second control voltage VP and is connected to the second terminal of the first transistor Q1, the second terminal of the second transistor Q2 is connected to the control terminal of the first transistor Q1, the first terminal of the second transistor Q2 is configured to receive a second supply voltage V_{L}. In the present embodiment, the first transistor Q1 and the second transistor Q2 are opposite-type bipolar transistors, with the control terminals being bases, the first terminals being emitters, and the second terminals being collectors.

In a preferred embodiment, the first transistor Q1 is a PNP type bipolar transistor, and the second transistor Q2 is an NPN type bipolar transistor.

The control circuit 10 is disposed on a path formed by the first transistor Q1 and the second transistor Q2 between the first supply voltage V_{H} and the second supply voltage V_{L}, and is used for disconnecting the path when the first control voltage V_{N} and/or the second control voltage V_{P} is out of a predetermined range.

The control circuit 10 is coupled between the first supply voltage V_{H} and the first transistor Q1, and includes a first comparison module 101 and a first switch module 102.

Wherein, the first comparison module 101 is used to output a first switch signal for turning off the first switch module 102 when the first control voltage V_{N} is out of a first predetermined range; the first switch module 102 is used to disconnect the first supply voltage V_{H} from the first transistor Q1 when receiving the first switch signal.

In the present embodiment, the first comparison module 101 is a first comparator U1, and the first switch module 102 is a first switch transistor M1. A first input terminal of the first comparator U1 receives the first control voltage V_{N}, a second input terminal of the first comparator U1 receives a first reference voltage V_{RH}, and the output terminal of the first comparator U1 is connected to a control terminal of the first switch transistor M1;

a first terminal of the first switch transistor M1 receives the first supply voltage V_{H}, and a second terminal of the first switch transistor M1 is connected to the first terminal of the first transistor Q1.

When the first control voltage V_{N}<the first reference voltage V_{RH}, the first switch signal outputted by the first comparator U1 controls the first switch transistor M1 to be turned off. Wherein, the first reference voltage V_{RH} may be equal to the first supply voltage V_{H}.

In a preferred embodiment, the first switch transistor M1 is a PMOS transistor; the control terminal of the first switch transistor M1 is a gate, the first terminal of the first switch transistor M1 is a source, and the second terminal of the first switch transistor M1 is a drain. The first switch signal is at a high level.

In a preferred embodiment, the first switch transistor M1 is a NMOS transistor; the control terminal of the first switch transistor M1 is a gate, the first terminal of the first switch transistor M1 is a drain, and the second terminal of the first switch transistor M1 is a source. The first switch signal is at a low level.

When a voltage disorder occurs (for example, a voltage disorder caused by static electricity or a circuit operation error), the first control voltage V_{N} or the second control voltage V_{P} may be changed. If the first control voltage V_{N} is caused to drop first, the first transistor Q1 is turned on, and the first supply voltage V_{H} is supplied to the control terminal of the second transistor Q2 when a voltage difference between the first terminal and the control terminal of the first transistor Q1 is greater than a turn-on voltage of the first transistor Q1, leading to the rise of the voltage V_{P} at the control terminal of the second transistor Q2; the second transistor Q2 is turned on when a voltage difference between the control terminal and the first terminal of the second transistor Q2 is greater than a turn-on voltage of the second transistor Q2, generating a latch path. If the second control voltage V_{P} is caused to rise first, the second transistor Q2 is turned on, and the second supply voltage V_{L} is supplied to the control terminal of the first transistor Q1 when a voltage difference between the first terminal and the control terminal of the second transistor Q2 is greater than a turn-on voltage of the second transistor Q2, leading to the drop of the first control voltage V_{N}; the first transistor Q1 is turned on when a voltage difference between the control terminal and the first terminal of the first transistor Q1 is greater than a turn-on voltage of the first transistor Q1, generating a latch path.

Therefore, in the case of the voltage disorder, the first control voltage V_{N} is directly or indirectly caused to drop. Comparing the first control voltage V_{N} with the first reference voltage V_{RH}, the first comparator U1 outputs the first switch signal to control the first switch transistor M1 to be turned off when the first control voltage V_{N}<the first reference voltage V_{RH}, so that the current path of the first supply voltage V_{H} is closed and no latch-up effect occurs.

The circuit for preventing latch-up provided by the present invention, by introducing the control circuit on the path formed by the first transistor and the second transistor between the first supply voltage and the second supply voltage, can disconnect the first supply voltage from the first transistor when the control voltage of the first transistor is out of a first predetermined range, so that a latch-up effect is prevented from occurring during power-on phase.

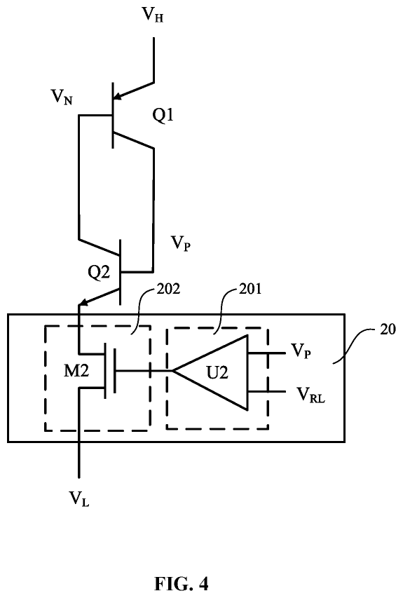

FIG. 4 illustrates a circuit diagram of a circuit for preventing latch-up according to a second embodiment of the present invention. Compared with the first embodiment, the difference is that the control circuit 20 is coupled between the second supply voltage V_{L} and the second transistor Q2, and comprises a second comparison module 201 and a second switch module 202.

Wherein, the second comparison module 201 is used to output a second switch signal for turning off the second switch module 202 when the second control voltage V_{P} is out of a second predetermined range; the second switch module 202 is used to disconnect the second supply voltage V_{L} from the second transistor Q2 when receiving the second switch signal.

In the present embodiment, the second comparison module 201 is a second comparator U2, and the second switch module 202 is a second switch transistor M2. A first input terminal of the second comparator U2 receives the second control voltage V_{P}, a second input terminal of the second comparator U2 receives a second reference voltage V_{RL}, and the output terminal of the second comparator U2 is connected to a control terminal of the second switch transistor M2;

a first terminal of the second switch transistor M2 receives the second supply voltage V_{L}, and a second terminal of the second switch transistor M2 is connected to the first terminal of the second transistor Q2.

When the second control voltage V_{P}>the second reference voltage V_{RL}, the second switch signal outputted by the second comparator U2 controls the second switch transistor M2 to be turned off. Wherein, the second reference voltage V_{RL} may be equal to the second supply voltage V_{L}.

In a preferred embodiment, the second switch transistor M2 is a PMOS transistor; the control terminal of the second switch transistor M2 is a gate, the first terminal of the second switch transistor M2 is a drain, and the second terminal of the second switch transistor M2 is a source. The second switch signal is at a high level.

In a preferred embodiment, the second switch transistor M2 is a NMOS transistor; the control terminal of the second switch transistor M2 is a gate, the first terminal of the second switch transistor M2 is a source, and the second terminal of the second switch transistor M2 is a drain. The second switch signal is at a low level.

In the case of the voltage disorder, the second control voltage V_{P} is directly or indirectly caused to rise. Comparing the second control voltage V_{P} with the second reference voltage V_{RL}, the second comparator U2 outputs a second switch signal to control the second switch transistor M2 to be turned off when the second control voltage V_{P}>the second reference voltage V_{RL}, so that the current path of the second supply voltage V_{L} is closed and no latch-up effect occurs.

The circuit for preventing latch-up provided by the present invention, by introducing the control circuit on the path formed by the first transistor and the second transistor between the first supply voltage and the second supply voltage, can disconnect the second supply voltage from the second transistor when the control voltage of the second transistor is out of a second predetermined range, so that a latch-up effect is prevented from occurring in power-on phase.

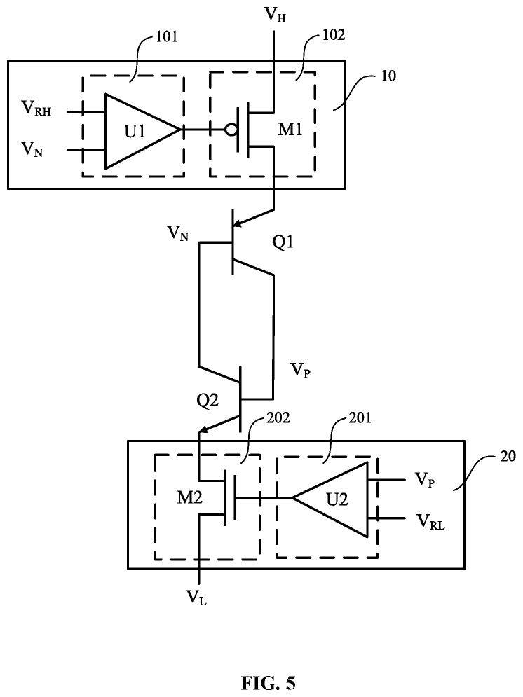

FIG. 5 illustrates a circuit diagram of a circuit for preventing latch-up according to a third embodiment of the present invention. Compared with the first embodiment, the difference is that the control circuit includes a first control circuit 10 and a second control circuit 20, wherein the first control circuit 10 is coupled between the first supply voltage V_{H} and the first transistor Q1, and includes the first comparison module 101 and the first switch module 102. The second control circuit 20 is coupled between the second supply voltage V_{L} and the second transistor Q2, and comprises a second comparison module 201 and a second switch module 202.

Wherein, the first comparison module 101 is used to output a first switch signal for turning off the first switch module 102 when the first control voltage V_{N} is out of a first predetermined range; the first switch module 102 is used to disconnect the first supply voltage V_{H} from the first transistor Q1 when receiving the first switch signal.

In the present embodiment, the first comparison module 101 is a first comparator U1, and the first switch module 102 is a first switch transistor M1. A first input terminal of the first comparator U1 receives the first control voltage V_{N}, a second input terminal of the first comparator U1 receives a first reference voltage V_{RH}, and the output terminal of the first comparator U1 is connected to a control terminal of the first switch transistor M1;

a first terminal of the first switch transistor M1 receives the first supply voltage V_{H}, and a second terminal of the first switch transistor M1 is connected to the first terminal of the first transistor Q1.

When the first control voltage V_{N}<the first reference voltage V_{RH}, the first switch signal outputted by the first comparator U1 controls the first switch transistor M1 to be turned off. Wherein, the first reference voltage V_{RH} may be equal to the first supply voltage V_{H}.

In a preferred embodiment, the first switch transistor M1 is a PMOS transistor; the control terminal of the first switch transistor M1 is a gate, the first terminal of the first switch transistor M1 is a source, and the second terminal of the first switch transistor M1 is a drain. The first switch signal is at a high level.

In a preferred embodiment, the first switch transistor M1 is a NMOS transistor; the control terminal of the first switch transistor M1 is a gate, the first terminal of the first switch transistor M1 is a drain, and the second terminal of the first switch transistor M1 is a source. The first switch signal is at a low level.

The second comparison module 201 is used to output a second switch signal for turning off the second switch module 202 when the second control voltage V_{P} is out of a second predetermined range; the second switch module 202 is used to disconnect the second supply voltage V_{L} from the second transistor Q2 when receiving the second switch signal.

In the present embodiment, the second comparison module 201 is a second comparator U2, and the second switch module 202 is a second switch transistor M2. A first input terminal of the second comparator U2 receives the second control voltage V_{P}, a second input terminal of the second comparator U2 receives a second reference voltage V_{RL}, and the output terminal of the second comparator U2 is connected to a control terminal of the second switch transistor M2;

a first terminal of the second switch transistor M2 receives the second supply voltage V_{L}, and a second terminal of the second switch transistor M2 is connected to the first terminal of the second transistor Q2.

When the second control voltage V_{P}>the second reference voltage V_{RL}, the second switch signal outputted by the second comparator U2 controls the second switch transistor M2 to be turned off. Wherein, the second reference voltage V_{RL} may be equal to the second supply voltage V_{L}.

In a preferred embodiment, the second switch transistor M2 is a PMOS transistor; the control terminal of the second switch transistor M2 is a gate, the first terminal of the second switch transistor M2 is a drain, and the second terminal of the second switch transistor M2 is a source. The second switch signal is at a high level.

In a preferred embodiment, the second switch transistor M2 is a NMOS transistor; the control terminal of the second switch transistor M2 is a gate, the first terminal of the second switch transistor M2 is a source, and the second terminal of the second switch transistor M2 is a drain. The second switch signal is at a low level.

In the case of the voltage disorder, the first control voltage V_{N} is directly or indirectly caused to drop and the second control voltage V_{P} to rise. Comparing the first control voltage V_{N} with the first reference voltage V_{RH} and the second control voltage V_{P} with the second reference voltage V_{RL}, the first comparator U1 outputs a first switch signal to control the first switch transistor M1 to be turned off when the first control voltage V_{N}<the first reference voltage V_{RH}, and the second comparator U2 outputs a second switch signal to control the second switch transistor M2 to be turned off when the second control voltage V_{P}>the second reference voltage V_{RL}, so that the current paths of the first supply voltage V_{H} and the second supply voltage V_{L} are closed and no latch-up effect occurs.

The circuit for preventing latch-up provided by the present invention, by introducing the control circuit on the path formed by the first transistor and the second transistor between the first supply voltage and the second supply voltage, can disconnect the first supply voltage from the first transistor when the first control voltage of the first transistor is out of a first predetermined range, and can disconnect the second supply voltage from the second transistor when the second control voltage of the second transistor is out of a second predetermined range, so that a latch-up effect is prevented from occurring during power-on phase.

The present invention further provides an integrated circuit comprising the circuit for preventing latch-up according to any one of above embodiments.

The embodiments in accordance with the present invention, as described above, are not described in detail, and are not intended to limit the present invention to be only the described particular embodiments. Obviously, many modifications and variations are possible in light of the above. These embodiments has been chosen and described in detail in the specification to explain the principles and practical applications of the present invention so that those skilled in the art can make good use of the present invention and the modified invention based on the present invention. The invention is to be limited only by the scope of the appended claims and the equivalents of the appended claims.

1. A circuit for preventing latch-up, comprising:
a first transistor having a control terminal, a first terminal, and a second terminal, wherein the control terminal of the first transistor is configured to receive a first control voltage, and the first terminal of the first transistor is configured to receive a first supply voltage;
a second transistor of a type opposite to that of the first transistor having a control terminal, a first terminal, and a second terminal, wherein the control terminal of the second transistor is configured to receive a second control voltage and is connected to the second terminal of the first transistor, the first terminal of the second transistor is connected to the control terminal of the first transistor, the second terminal of the second transistor is configured to receive a second supply voltage;
a control circuit disposed on a path formed by the first transistor and the second transistor between the first supply voltage and the second supply voltage, and used for disconnecting the path when the first control voltage and/or the second control voltage is out of a predetermined range.

2. The circuit for preventing latch-up according to claim 1, wherein the control circuit is coupled between the first supply voltage and the first transistor, and comprises a first comparison module and a first switch module,
the first comparison module is used to output a first switch signal for turning off the first switch module when the first control voltage is out of a first predetermined range;
the first switch module is used to disconnect the first supply voltage from the first transistor when receiving the first switch signal.

3. The circuit for preventing latch-up according to claim 2, wherein the first comparison module is a first comparator, and the first switch module is a first switch transistor;
a first input terminal of the first comparator receives the first control voltage, a second input terminal of the first comparator receives a first reference voltage, and the output terminal of the first comparator is connected to a control terminal of the first switch transistor;
a first terminal of the first switch transistor receives the first supply voltage, and a second terminal of the first switch transistor is connected to the first terminal of the first transistor.

4. The circuit for preventing latch-up according to claim 1, wherein the control circuit is coupled between the second supply voltage and the second transistor, and comprises a second comparison module and a second switch module,
the second comparison module is used to output a second switch signal for turning off the second switch module when the second control voltage is out of a second predetermined range;
the second switch module is used to disconnect the second supply voltage from the second transistor when receiving the second switch signal.

5. The circuit for preventing latch-up according to claim 4, wherein the second comparison module is a second comparator, and the second switch module is a second switch transistor;
a first input terminal of the second comparator receives the second control voltage, a second input terminal of the second comparator receives a second reference voltage, and the output terminal of the second comparator is connected to a control terminal of the second switch transistor;
a first terminal of the second switch transistor receives the second supply voltage, and a second terminal of the second switch transistor is connected to the first terminal of the second transistor.

6. The circuit for preventing latch-up according to claim 1, wherein the control circuit is coupled between the first supply voltage and the first transistor, and between the second supply voltage and the second transistor, and comprises a first comparison module, a first switch module, a second comparison module and a second switch module,
the first comparison module is used to output a first switch signal for turning off the first switch module when the first control voltage is out of a first predetermined range;
the first switch module is used to disconnect the first supply voltage from the first transistor when receiving the first switch signal;
the second comparison module is used to output a second switch signal for turning off the second switch module when the second control voltage is out of a second predetermined range;
the second switch module is used to disconnect the second supply voltage from the second transistor when receiving the second switch signal.

7. The circuit for preventing latch-up according to claim 6, wherein the first comparison module is a first comparator, and the first switch module is a first switch transistor; the second comparison module is a second comparator, and the second switch module is a second switch transistor;
a first input terminal of the first comparator receives the first control voltage, a second input terminal of the first comparator receives a first reference voltage, and the output terminal of the first comparator is connected to a control terminal of the first switch transistor;
a first terminal of the first switch transistor receives the first supply voltage, and a second terminal of the first switch transistor is connected to the first terminal of the first transistor;
a first input terminal of the second comparator receives the second control voltage, a second input terminal of the second comparator receives a second reference voltage, and the output terminal of the second comparator is connected to a control terminal of the second switch transistor;
a first terminal of the second switch transistor receives the second supply voltage, and a second terminal of the second switch transistor is connected to the first terminal of the second transistor.

8. The circuit for preventing latch-up according to claim 7, wherein the first switch transistor is a PMOS transistor, and the second switch transistor is an NMOS transistor.

9. The circuit for preventing latch-up according to claim 1, wherein the first transistor is a PNP transistor, and the second transistor is an NPN transistor.

10. The circuit for preventing latch-up according to claim 9, wherein the first supply voltage is larger than the second supply voltage.

11. An integrated circuit, comprising the circuit for preventing latch-up according to claim 1.
